(19) United States
(12) Patent Application Publication
(10) Pub. No.: US 2017/0323955 A1
(43) Pub. Date: Nov. 9, 2017

(54) APPARATUS AND METHODS OF FORMING FIN STRUCTURES WITH SIDEWALL LINER

(71) Applicant: Intel Corporation, Santa Clara, CA (US)

(72) Inventors: Willy Rachmady, Beaverton, OR (US); Matthew V. Metz, Portland, OR (US); Chandra S. Mohapatra, Hillsboro, OR (US); Gilbert Dewey, Hillsboro, OR (US); Jack T. Kavalieros, Portland, OR (US); Anand S. Murthy, Portland, OR (US); Nadia M. Rahhal-Orabi, Lake Oswego, OR (US); Tahir Ghani, Portland, OR (US); Glenn A. Glass, Portland, OR (US)

(73) Assignee: Intel Corporation, Santa Clara, CA (US)

(21) Appl. No.: 15/528,743

(22) PCT Filed: Dec. 23, 2014
(86) PCT No.: PCT/US2014/072089

§ 371 Date: May 22, 2017

(51) Int. Cl. H01L 29/66; H01L 29/78; H01L 21/762; H01L 29/04; H01L 27/108; H01L 29/06

(52) U.S. Cl. CPC H01L 29/66795; H01L 29/0649; H01L 29/785; H01L 29/66484; H01L 21/762; H01L 29/04; H01L 27/108; H01L 2029/7858

(57) ABSTRACT

An includes an epitaxial sub-fin structure disposed on a substrate, wherein a first portion of the sub-fin structure is disposed within a portion of the substrate, and a second portion of the sub-fin structure is disposed adjacent a dielectric material. A fin device structure is disposed on the sub-fin structure, wherein the fin device structure comprises the epitaxial material. A liner is disposed between the second portion of the sub-fin structure and the dielectric material. Other embodiments are described herein.

### BACKGROUND

Integration of epitaxial materials, such as indium aluminum phosphide, for example, onto substrates, such as silicon substrates, is highly desired in microelectronic device applications. High quality epitaxial materials enhance the performance for such applications as system on chip (SoC), high voltage and RF devices, as well as for complementary metal oxide silicon (CMOS) applications. This integration involves fabrication challenges that may arise due to the mismatch in lattice properties between the two materials.

### BRIEF DESCRIPTION OF THE DRAWINGS

While the specification concludes with claims particularly pointing out and distinctly claiming certain embodiments, the advantages of these embodiments can be more readily ascertained from the following description of embodiments when read in conjunction with the accompanying drawings in which:

FIGS. 1a-1i represent cross-sectional views of structures according to various embodiments.

FIGS. 2a-2c represents cross-sectional views of structures according to embodiments.

FIG. 3 represents a flow chart of a method according to embodiments.

FIG. 4 is an interposer implementing one or more embodiments.

FIG. 5 is a computing device built in accordance with an embodiment.

### DETAILED DESCRIPTION

In the following detailed description, reference is made to the accompanying drawings that show, by way of illustration, specific embodiments in which the methods and structures may be practiced. These embodiments are described in sufficient detail to enable those skilled in the art to practice the embodiments. It is to be understood that the various embodiments, although different, are not necessarily mutually exclusive. For example, a particular feature, structure, or characteristic described herein, in connection with one embodiment, may be implemented within other embodiments without departing from the spirit and scope of the embodiments. In addition, it is to be understood that the location or arrangement of individual elements within each disclosed may be modified without departing from the spirit and scope of the embodiments. In the drawings, like numerals may refer to the same or similar functionality throughout the several views.

Various operations will be described as multiple discrete operations, in turn, in a manner that is most helpful in understanding the embodiments herein, however, the order of description should not be construed to imply that these operations are necessarily order dependent. In particular, these operations need not be performed in the order of presentation.

Implementations of the embodiments may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the embodiments herein.

Methods and associated structures of forming and utilizing microelectronic structures, such as epitaxial fin structures formed on substrates, are described. Those methods/structures may include an epitaxial sub-fin structure disposed on a substrate, wherein a first portion of the sub-fin structure is disposed within a portion of the substrate, and a second portion of the sub-fin structure is disposed adjacent an isolation material. A fin device structure is disposed on the sub-fin structure, wherein the fin device structure comprises the epitaxial material. A liner is disposed between the second portion of the sub-fin structure and the isolation material, the liner comprising a barrier between the second portion of the sub-fin structure and the isolation material. The liner provides a chemically stable, non-reactive barrier between the sub-fin structure and the isolation material so that defect formation, such as stacking faults, is reduced. In an embodiment, the amount of defects may comprise less than 1 part per million (ppm).

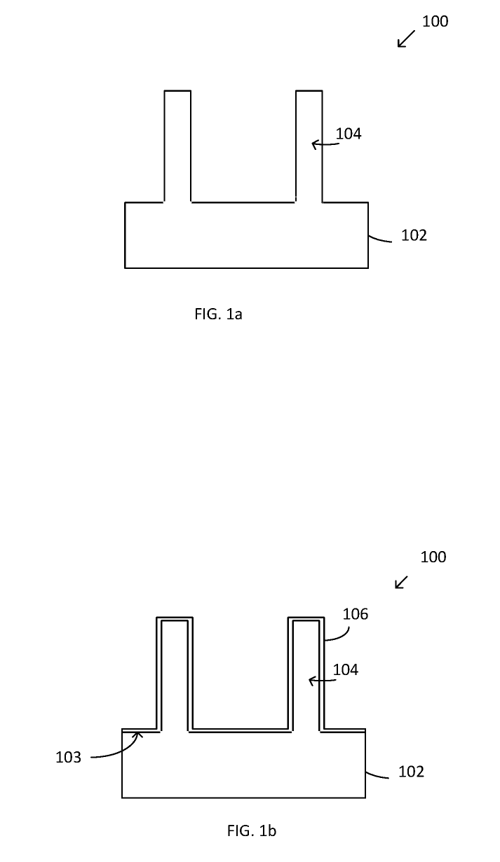

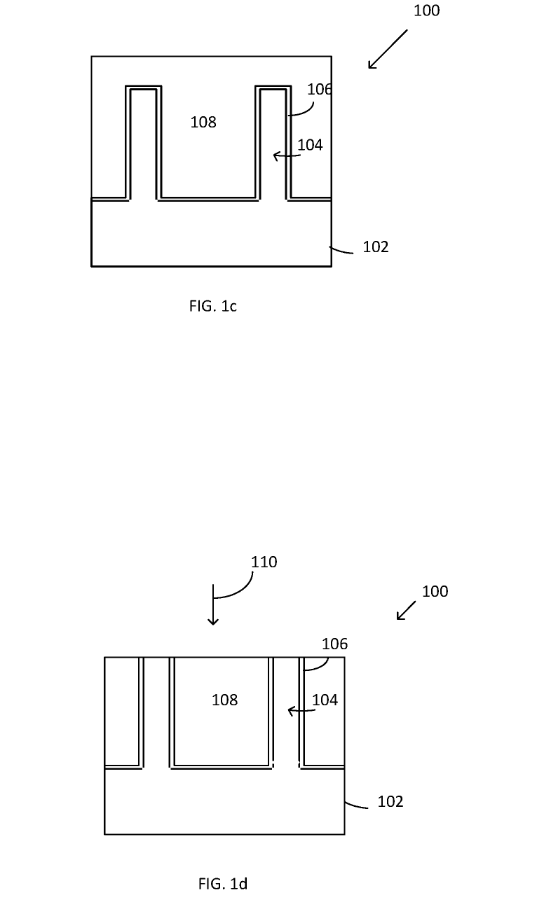

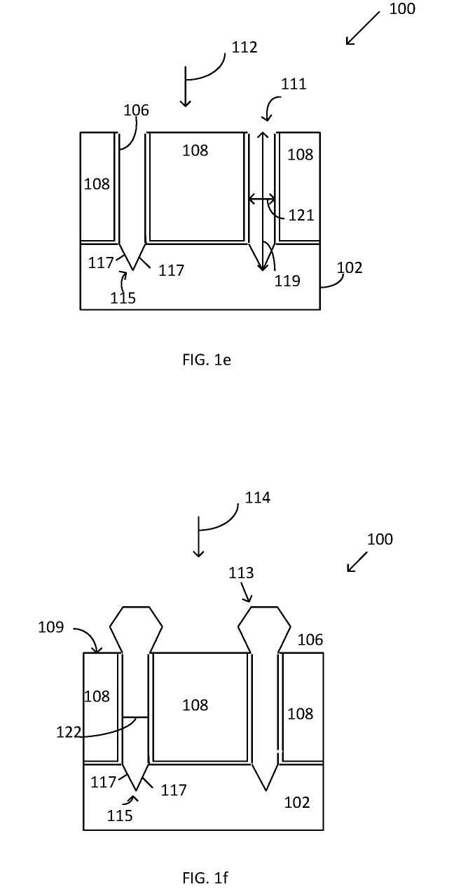

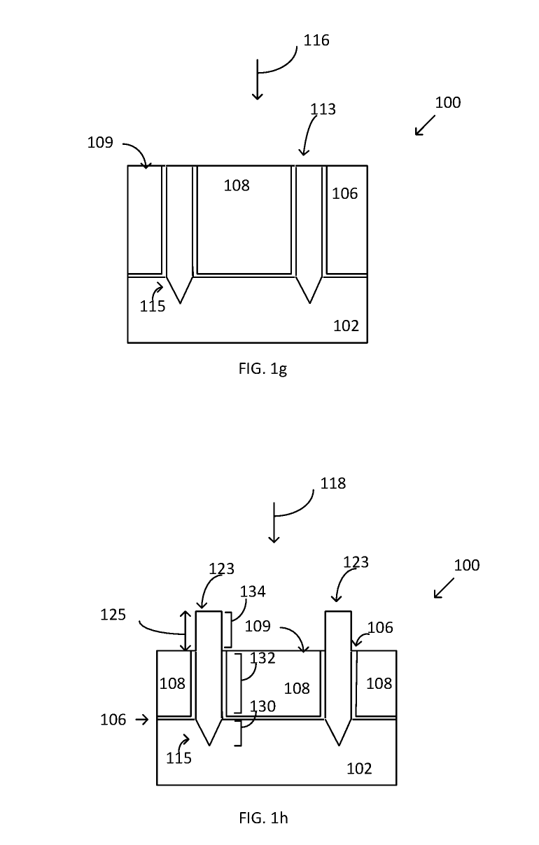

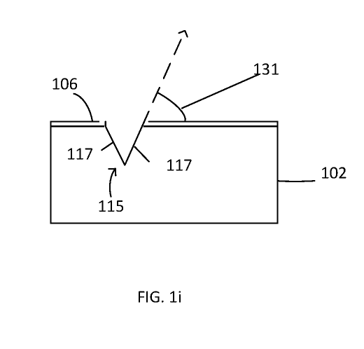

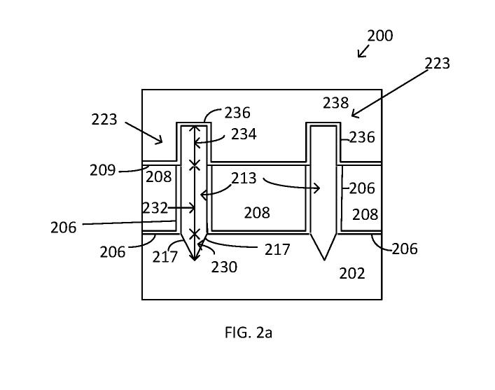

FIGS. 1a-1i illustrate cross-sectional views of embodiments of forming microelectronic structures, such as epitaxial fin structures disposed on a substrate, for example. In an embodiment, a microelectronic device 100 may comprise a substrate 102 (FIG. 1a). In an embodiment, the substrate 102 may comprise a silicon substrate, and may be p-doped with a p-type material/element such as boron, for example. In another embodiment, the substrate 102 may comprise circuit elements, such as transistors and passive elements, for example. In an embodiment, the substrate 102 may comprise a portion of a CMOS substrate 102, and may comprise p-type metal oxide semiconductor (PMOS) and n type metal oxide semiconductor (NMOS) transistors. In an embodiment, the microelectronic device 100 may comprise a portion of a tri-gate transistor, a gate all around (GAA) transistor, or any other type of multi-gate transistor. In an embodiment, the microelectronic device 100 may comprise a portion of a compound (including group III-V material) transistor.

A sacrificial fin 104, which may comprise silicon in an embodiment, may be disposed on the substrate 102. In an embodiment, the sacrificial fin 104 may be oriented such that it is orthogonally disposed on the substrate 102. A liner 106 may be formed on the sacrificial fin 104 and on a surface 103 of the substrate 102 (FIG. 1b). In other embodiments, the liner may not be formed on the substrate surface 103, and in some embodiments, the liner 106 may be formed only on the sacrificial fin 104. In an embodiment, the liner 106 may comprise a material that does not chemically react with group III through group V materials. In an embodiment, the liner 106 may comprise a thickness of less than about 100 angstroms. In an embodiment, the liner material may comprise at least one of silicon nitride, silicon oxynitride, hafnium oxide, and aluminum oxide. In an embodiment, the liner 106 does not comprise silicon dioxide. The liner 106 may be formed utilizing a deposition process, such as a physical vapor deposition (PVD), an atomic layer deposition (ALD) and/or a chemical vapor deposition (CVD) process, for example.

In an embodiment, an isolation material 108 may be formed on the liner 106 (FIG. 1c). The isolation material 108 may comprise a dielectric material, such as silicon dioxide, and may comprise a shallow trench isolation (STI) material in some cases. The isolation material 108 may comprise such materials as carbon doped oxide (CDO), silicon nitride, silicon oxyntiride, silicon carbide, organic polymers such as perfluorocyclobutane or polytetrafluoroethylene, fluorosilicate glass (FSG), and/or ganosilicates such as silsesquioxane, siloxane, or organosilicate glass, in embodiments. In an embodiment, the isolation material 108 may comprise multiple layers of different materials. The isolation material 108 may comprise a chemical vapor deposition (CVD) deposited material in an embodiment.

A portion of the liner 106 may be disposed between the substrate 102 and the isolation material 108. In an embodiment, the liner 106 may extend in a continuous layer from the top surface of the substrate 102 to a top portion of the sacrificial fin 104. In an embodiment, the isolation material 108 may be removed by utilizing a removal process, such as a chemical mechanical polishing (CMP) process 110, in order to planarize the top surface of the isolation material 108 with the top surface of the sacrificial silicon fin 104 (FIG. 1d). In other embodiments, other removal processes may be utilized, such as various etching processes for example. A portion of the liner 106 may be removed from the top surface of the sacrificial silicon fin 104 during the CMP process 110.

In an embodiment, the sacrificial fin structure 104 may be removed to form an opening/trench 111 utilizing a suitable removal process 112, for example, wherein a portion of the substrate 102 underlying the sacrificial fin 104 is also removed (FIG 1e). In an embodiment, a wet etch, such as a tetramethylammonium hydroxide (TMAH) etchant and/or an etchant comprising ammonium hydroxide, for example, may be utilized to remove the sacrificial fin structure 104, however other dry and/or wet etches may be utilized according to the particular application. In an embodiment, the removal process 112 may comprise an anisotropic etching process, wherein the etchants of the removal process 112 may create (111) facets in a bottom portion 115 of the substrate 102.

The removal of the sacrificial fin structure 104 may expose the liner 106 in the opening 111. In an embodiment, the bottom portion 115 of the trench 111 may be formed/etched within a portion of the substrate 102. In an embodiment, the bottom portion 115 of the trench opening 111 may comprise a tapered shape wherein the shape resembles a V-shape.

In an embodiment, the bottom portion 115 of the trench 111 may comprise sidewalls 117 that comprise (111) silicon planes of the substrate 102. In an embodiment, the sidewalls 117 may comprise an angle 131, and in some embodiments, the angle 131 may comprise between about 52 degrees and about 57 degrees (FIG. 1i) with respect to the substrate 102. In other embodiments, the bottom portion 115 of the trench 111 may comprise a more rounded profile, other than a V-shape. In some embodiments, the bottom portion 115 of the trench 111 may comprise other shapes, depending upon the particular application. In an embodiment, the trench opening 111 may comprise an aspect ratio trapping (ART) trench, wherein a ratio of a depth 119 of the trench opening 111 to a width 121 of the trench 111 opening may comprise at least about 2:1 (referring back to FIG. 1e). In other embodiments, the ratio may comprise 1.5, 1.7, 1.9, 2.1, 2.3, 2.5, 2.7, for example.

In an embodiment, an epitaxial material 113, such as a III-V epitaxial material 113, may be formed utilizing a suitable epitaxial process 114, within the trench opening 111 (FIG. 1f. In an embodiment, the epitaxial material 113 may commence growing on the (111) surfaces 117 of the substrate 102. In an embodiment, a first portion of the epitaxial material 113 may be formed/grown on the bottom portion of the trench opening, within a portion of the substrate 102, wherein the epitaxial material 113 may be formed on the (111) planes of the silicon substrate 102. In an embodiment, a substrate 102 interface with the first portion of the epitaxial material 113 may comprise at least one (111) silicon plane. In an embodiment, a second portion of the epitaxial material 113 may be formed/grown on the liner 106 adjacent the isolation material 108.

In an embodiment, an additional portion of the epitaxial material 113 may be formed/grown above and adjacent a surface 109 of the isolation material 108, and may extend above the surface 109 of the isolation material 108. In an embodiment, the epitaxial material may comprise any material comprising elements from group III, IV, and/or V of the periodic table, and combinations thereof. In an embodiment, the epitaxial material may be grown utilizing any suitable epitaxial process, and may comprise a width 122 between about 4 nm and about 80 nm, in some embodiments.

In an embodiment, the epitaxial material 113 may comprise a III-V material, such as at least one of a gallium nitride, indium gallium nitride, indium phosphide or an indium aluminum phosphide material, gallium arsenide, indium gallium arsenide, and indium arsenide, for example. In an embodiment, the epitaxial material 113 may comprise multiple layers of epitaxial material that may be formed upon one another, which may comprise a stack of multiple, heterogeneous epitaxial layers, in which the lattice constants of the various layers may be different from one another. In an embodiment, the epitaxial material 113 may comprise multiple layers of lattice mismatched epitaxial materials. Because the liner 106 is disposed between the second portion of epitaxial layer 113 and the isolation material 108, there is no reactivity between the isolation material 108 and the second portion of the epitaxial material 113.

The embodiments herein which include the liner 106, prevent the reactivity and/or defect formation at the interface between the isolation material 108 and the epitaxial material 113. In an embodiment, the liner 106 comprises a non-reacting, chemically stable non-silicon dioxide layer that provides a physical and/or chemical barrier between the isolation material 108 and the epitaxial material 113. The liner material 106 may alter the growth conditions of the epitaxial material 113 such that defect formation in the epitaxial material 113 is greatly reduced or non-existent. The embodiments herein enable the formation of a virtually defect free epitaxial layer 113.

In an embodiment, the additional portion of the epitaxial material 113 disposed above the surface 109 of the isolation material 108 may be removed utilizing a removal process 116, such as a CMP process, for example, to become planarized with the surface 109 of the isolation material 108 (FIG. 1g).

In an embodiment, a portion of the isolation material 108 and the liner 106 may be recessed utilizing a removal process 118, such as a CMP process, wherein an exposed portion of the epitaxial material 113 forms/comprises at least one fin device structure 123 (FIG. 1h). In an embodiment, the fin device structure 123 may lack the liner 106 disposed on the sidewalls, and may extend above the surface 109 of the isolation material 108, and may comprise a height 125. In an embodiment, a portion of the fin device structure 123 may comprise a portion of the liner 106 on a portion of a sidewall region.

In an embodiment, the fin device structure 123 height 125 may comprise about 4 nm to about 80 nm. A portion of the fin device structure 123 may comprise a portion of a multi-gate device, such as a channel region of a multi-gate device, for example, and may be coupled with source/drain regions, in an embodiment. In an embodiment, the epitaxial material 113 comprises a first portion 130 disposed within a portion of the substrate 102, a second portion 132 disposed between the isolation material 108 and the liner 106, and a third portion (comprising the fin device structure 123) disposed above the surface 109 of the isolation material 108, and extending from the second portion 132. In an embodiment, the first, second and third portions 130, 132, 134 comprise the epitaxial material 113, and are grown in an epitaxial growth process, such as the epitaxial growth process 114 of FIG 1f.

In an embodiment, neither the first or third portions 130, 134 include the liner 106 disposed on the sidewalls of the epitaxial material 113, however the second portion 132 of the epitaxial material 113 comprises the liner on the sidewalls of the epitaxial material 113. A portion of the liner 106 is disposed between the isolation material 108 and the substrate 102 adjacent to the epitaxial material 113, in an embodiment. The first and second portions 130, 132 of the epitaxial material 113 comprise a sub-fin structure, in an embodiment, wherein the fin device structure 123 is disposed on the sub-fin structure, wherein the sub-fin structure is disposed below the surface 109 of the isolation material 108.

In an embodiment, a plurality of transistors, such as metal-oxide-semiconductor field-effect transistors (MOSFET or simply MOS transistors), may be fabricated on the substrate 102, and may in general comprise the epitaxial material 113, and may include the fin device structure 123. In various implementations of the embodiments, the MOS transistors may be planar transistors, nonplanar transistors, or a combination of both. Nonplanar transistors include FinFET transistors such as double-gate transistors and tri-gate transistors, and wrap-around or gate all around (GAA) transistors such as nanoribbon and nanowire transistors. The embodiments herein may be carried out using nonplanar and/or planar transistors.

Each MOS transistor comprising the epitaxial material/fin device structure may include a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the embodiment, the gate electrode may consist of a combination of U-shaped structures and planar, non-U-shaped structures. For example, the gate electrode may consist of one or more U-shaped metal layers formed atop one or more planar, non-U-shaped layers.

In some implementations of the embodiments, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions.

An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

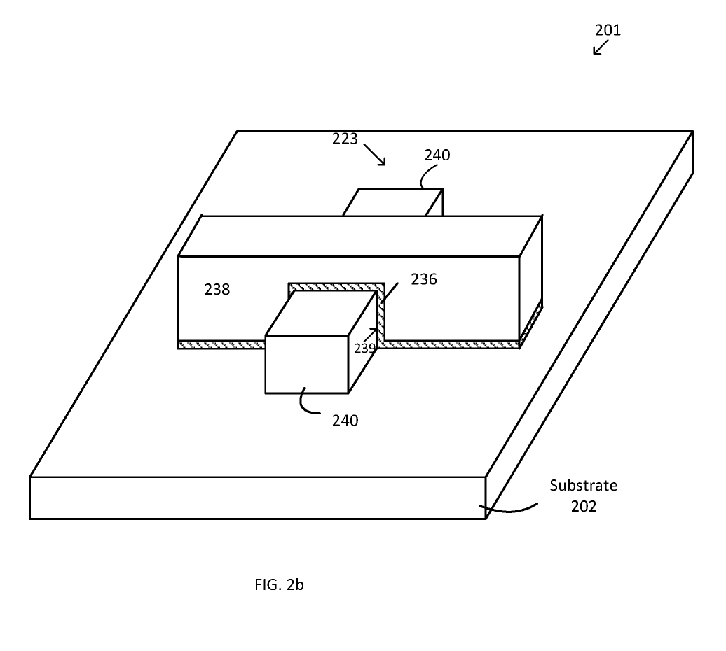

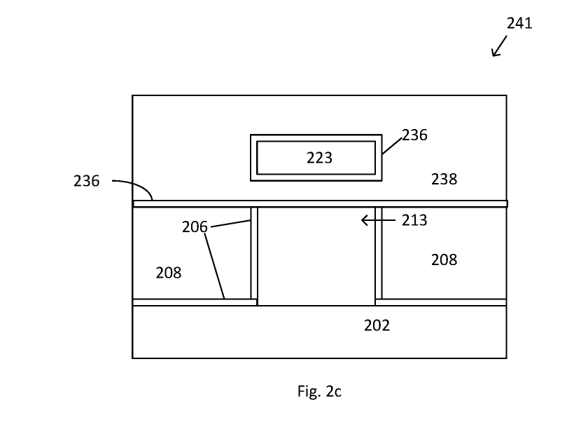

FIG. 2a depicts a cross section of a portion of microelectronic device 200, such as a tri-gate or other type of multi-gate device 200. In an embodiment, the epitaxial material 213 comprises a first portion 230 disposed at least partially within the substrate 202. In an embodiment, the first portion 230 comprises bottom sidewalls 217 that are angular (similar to the sidewalls of FIG. 1h), wherein the first portion 230 may comprise a V-shape in an embodiment. Other embodiments of the bottom sidewalls 217 may comprise more rounded sidewalls, or other shapes according to the particular application. In an embodiment, the bottom sidewalls 217 of the epitaxial material 213 are adjacent to (111) planes of a silicon substrate 202.

In an embodiment, the epitaxial material 213 may comprise a second portion 232, wherein a liner material 206, similar to the liner material 106 of FIG. 1h, may line the sidewalls of the epitaxial material 213. The liner 206 is disposed between the second portion 232 of the epitaxial material 213 and the isolation material 208, and provides a physical barrier layer between the epitaxial layer and the isolation layer 208, in an embodiment. A gate oxide 236 may be disposed on a third portion 234 of the epitaxial material 213, and on a portion of the liner 206 and on a surface 209 of the isolation material 208. The gate oxide 236 may comprise an oxide material, such as a silicon dioxide material. In an embodiment, the gate oxide material may comprise a high k dielectric material, wherein the dielectric material comprises a dielectric constant greater than that of silicon dioxide.

High-k dielectric materials may include hafnium dioxide (HfO₂), hafnium silicon oxide, lanthanum oxide, lanthanum aluminum oxide, zirconium dioxide (ZrO₂), zirconium silicon oxide, titanium dioxide (TiO₂), tantalum pentaoxide (Ta₂O₅), barium strontium titanium oxide, barium titanium oxide, strontium titanium oxide, yttrium oxide, aluminum oxide, lead scandium tantalum oxide, and lead zinc niobate, for example. In an embodiment, the gate oxide 236 may be directly disposed on a portion of the liner 206.

In an embodiment, a gate material 238 may be disposed on the gate oxide 236. In an embodiment, gate materials include, for example, materials such as titanium, tungsten, tantalum, aluminum, and alloys thereof, and alloys with rare earth elements, such as erbium, dysprosium or noble metals such as platinum, and nitrides such as tantalum nitride and titanium nitride. In an embodiment, a portion of the liner 206 is also disposed between the isolation material 208 and the substrate 202 adjacent to the epitaxial material 213. In an embodiment, the third portion 234 of the epitaxial material 213 comprises a fin device structure 223, and may comprise a portion of a channel region with the gate oxide 236 and the gate material 238 disposed thereon.

FIG. 2b depicts a portion of a multi-gate transistor 200 wherein source/drain regions 240 are coupled with a channel region 239 of the fin device structure 223. In an embodiment, materials for sources and/or drains may include, for example, silicon, carbon doped silicon, and phosphorus doped silicon, for NMOS, and boron doped silicon germanium, SixGe_{1-X}, boron doped germanium, boron doped germanium tin, GeₓSn_{1-X}, and p-doped III-V compounds for PMOS applications. In an embodiment, a gate oxide 236 is disposed on the channel region 239 of the fin device structure 223, and a gate material 238 is disposed on the gate oxide 236.

FIG. 2c depicts a gate all around structure 241, which may comprise a nanoribbon and/or a nanowire structure, for example. A gate oxide 236 may be disposed all around (on all sides) the fin device structure 223, and on the liner 206 and on the isolation material 208, in an embodiment. Epitaxial material 213 is disposed beneath the fin device structure 223 and may be disposed on the substrate 202 and adjacent the isolation material 208. The liner 206 is disposed between the epitaxial material 213 and the isolation material 208. A portion of the liner 206 may be disposed between the substrate 202 and the isolation material.

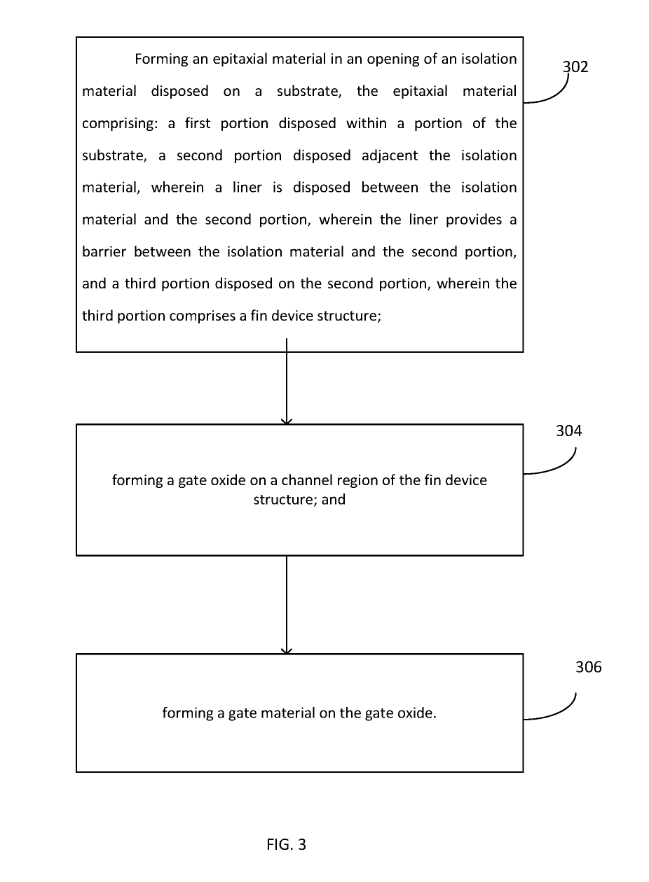

FIG. 3 depicts a flow chart of a method of forming an epitaxial fin structure on a substrate, according to embodiments. Block 302 includes forming an epitaxial material in an opening of an isolation material disposed on a substrate, the epitaxial material comprising: a first portion disposed within a portion of the substrate, a second portion disposed adjacent the isolation material, wherein a liner is disposed between the isolation material and the second portion, wherein the liner provides a barrier between the isolation material and the second portion, and a third portion disposed on the second portion, wherein the third portion comprises a fin device structure.

Block 304 includes forming a gate oxide on a channel region of the fin device structure. Block 306 includes forming a gate material on the gate oxide. In some embodiments, prior to forming the epitaxial material, the opening in the isolation material may be formed by providing a sacrificial fin on the substrate, forming the liner on the sacrificial fin and on the substrate, forming the isolation material on the liner, and removing the sacrificial fin, wherein the liner is disposed on the sidewalls of the isolation material and on the substrate.

In an embodiment, the fin device structures of the embodiments herein may be coupled with any suitable type of package structures capable of providing electrical communications between a microelectronic device, such as a die and a next-level component to which the package structures may be coupled (e.g., a circuit board). In another embodiment, the devices herein may be coupled with a package structure that may comprise any suitable type of package structures capable of providing electrical communication between a die and an upper integrated circuit (IC) package coupled with the devices herein.

The devices of the embodiments herein may comprise circuitry elements such as logic circuitry for use in a processor die, for example. Metallization layers and insulating material may be included in the devices herein, as well as conductive contacts/bumps that may couple metal layers/interconnects to external devices/layers. The devices described in the various figures herein may comprise portions of a silicon logic die or a memory die, for example, or any type of suitable microelectronic device/die. In some embodiments the devices may further comprise a plurality of dies, which may be stacked upon one another, depending upon the particular application. In some cases the die(s) of the devices herein may be located/attached/embedded on either the front side, back side or on/in some combination of the front and back sides of a package structure. In an embodiment, the die(s) may be partially or fully embedded in a package structure.

The various embodiments of the device structures included herein may be used for SOC products that may require integrated transistor, such as smart phones, notebooks, tablets, and other electronic mobile devices. Fabrication of devices, such as multi-gate transistor devices including fin structures with a liner structure, is described. Epitaxial intermixing and/or reaction with silicon dioxide isolation materials, for example, is prevented by the use of the barrier liner between the isolation material and the epitaxial material. A sub fin sidewall passivation is provided. The epitaxial quality of III-V material is improved by reducing the number of defects emanating from the isolation material sidewalls during epitaxial growth. Prevention of epitaxial dopant out-diffusion to the STI is enabled, as well as prevention of fin oxidation by downstream device processes. Enablement of the fabrication of non-silicon CMOS on silicon wafers is realized.

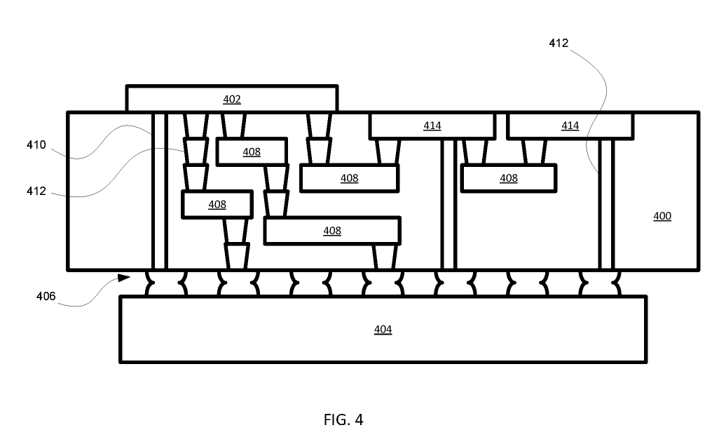

FIG. 4. illustrates an interposer 400 that includes one or more embodiments included herein. The interposer 400 is an intervening substrate used to bridge a first substrate 402 to a second substrate 404. The first substrate 402 may be, for instance, an integrated circuit die, wherein the die may comprise the device structures, such as the fin device structures, of the embodiments herein. The second substrate 404 may be, for instance, a memory module, a computer motherboard, or another integrated circuit die, wherein the second substrate 404 may incorporate the device structures, such as the fin device structures, of the embodiments herein. Generally, the purpose of an interposer 404 is to spread a connection to a wider pitch and/or to reroute a connection to a different connection. For example, an interposer 400 may couple an integrated circuit die to a ball grid array (BGA) 406 that can subsequently be coupled to the second substrate 404. In some embodiments, the first and second substrates 402, 404 are attached to opposing sides of the interposer 400. In other embodiments, the first and second substrates 402, 404 are attached to the same side of the interposer 400. And in further embodiments, three or more substrates are interconnected by way of the interposer 400.

The interposer 400 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 408 and vias 410, including but not limited to through-silicon vias (TSVs) 412. The interposer 400 may further include embedded devices 414, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 400.

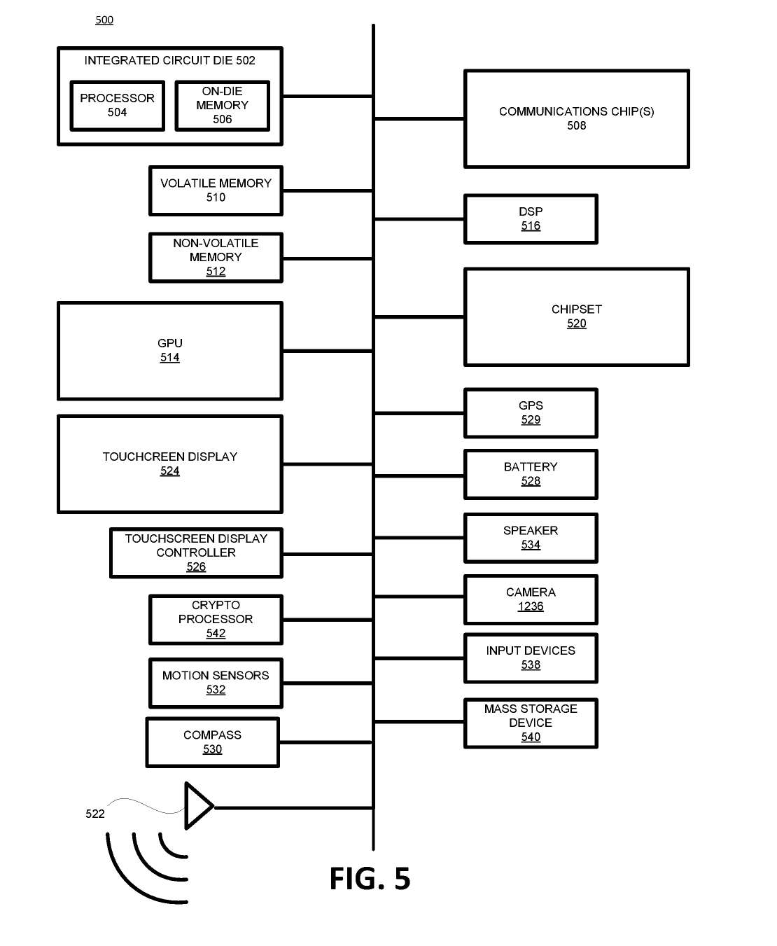

FIG. 5 illustrates a computing device 500 that may include embodiments of device structures described herein. The computing device 500 may include a number of components. In an embodiment, these components are attached to one or more motherboards. In an alternate embodiment, these components are fabricated onto a single system-on-a-chip (SoC) die rather than a motherboard. The components in the computing device 500 include, but are not limited to, an integrated circuit die 502 and at least one communication chip 508. In some implementations the communication chip 508 is fabricated as part of the integrated circuit die 502. The integrated circuit die 502 may include a CPU 504 as well as on-die memory 506, often used as cache memory, that can be provided by technologies such as embedded DRAM (eDRAM) or spin-transfer torque memory (STTM or STTM-RAM).

Computing device 500 may include other components that may or may not be physically and electrically coupled to the motherboard or fabricated within an SoC die. These other components include, but are not limited to, volatile memory 510 (e.g., DRAM), non-volatile memory 512 (e.g., ROM or flash memory), a graphics processing unit 514 (GPU), a digital signal processor 516, a crypto processor 542 (a specialized processor that executes cryptographic algorithms within hardware), a chipset 520, an antenna 522, a display or a touchscreen display 524, a touchscreen controller 526, a battery 528 or other power source, a power amplifier (not shown), a global positioning system (GPS) device 529, a compass 530, a motion coprocessor or sensors 532 (that may include an accelerometer, a gyroscope, and a compass), a speaker 534, a camera 536, user input devices 538 (such as a keyboard, mouse, stylus, and touchpad), and a mass storage device 540 (such as hard disk drive, compact disk (CD), digital versatile disk (DVD), and so forth).

The communications chip 508 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some s they might not. The communication chip 508 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 508. For instance, a first communication chip 508 may be dedicated to shorter range wireless communications such as Wi-Fi and Bluetooth and a second communication chip 508 may be dedicated to longer range wireless communications such as GPS, EDGE, GPRS, CDMA, WiMAX, LTE, Ev-DO, and others.

The processor 504 of the computing device 500 includes one or more devices, such as transistors or metal interconnects, that are formed in accordance with embodiments herein. The term “processor” may refer to any device or portion of a device that processes electronic data from registers and/or memory to transform that electronic data into other electronic data that may be stored in registers and/or memory.

The communication chip 508 may also include one or more devices, such as transistors device structures and package structures, that are formed in accordance with embodiments herein. In further embodiments, another component housed within the computing device 500 may contain one or more devices, such as transistors device structures and associated package structures, that are formed in accordance with embodiments herein.

In various embodiments, the computing device 500 may be a laptop computer, a netbook computer, a notebook computer, an ultrabook computer, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 500 may be any other electronic device that processes data.

The above description of illustrated embodiments, including what is described in the Abstract, is not intended to be exhaustive or to limit the embodiments to the precise forms disclosed. While specific implementations of, and examples for, the embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the embodiments is to be determined entirely by the following claims, which are to be construed in accordance with established doctrines of claim interpretation.

Although the foregoing description has specified certain steps and materials that may be used in the methods of the embodiments, those skilled in the art will appreciate that many modifications and substitutions may be made. Accordingly, it is intended that all such modifications, alterations, substitutions and additions be considered to fall within the spirit and scope of the embodiments as defined by the appended claims. In addition, the Figures provided herein illustrate only portions of exemplary microelectronic devices and associated package structures that pertain to the practice of the embodiments. Thus the embodiments are not limited to the structures described herein.

1-25. (canceled)

26. A microelectronic device structure comprising:
a first portion of an epitaxial material disposed within a portion of a substrate;
a second portion of the epitaxial material disposed adjacent a dielectric material,
wherein a liner material is disposed between the dielectric material and the second portion;
a third portion of the epitaxial material disposed on the second portion, wherein
the third portion comprises a fin device structure;
a gate oxide disposed on the fin device structure; and
a gate material disposed on the gate oxide.

27. The structure of claim 26 wherein a portion of the liner is disposed on the silicon substrate adjacent the epitaxial material and between the dielectric material and the substrate.

28. The structure of claim 26 wherein the epitaxial material comprises a material selected from the group consisting of group III elements, group IV elements, and group V elements.

29. The structure of claim 26 wherein the microelectronic device comprises a device selected from the group consisting of a multi-gate transistor and a gate all around transistor.

30. The structure of claim 26 wherein a substrate interface with the first portion of the epitaxial material comprises at least one (111) silicon plane.

31. The structure of claim 26 wherein the liner is disposed directly on the gate oxide.

32. The structure of claim 26 wherein the liner material is chemically non-reactive

33. The structure of claim 26 wherein the fin device structure extends above a surface of the dielectric material.

34. A microelectronic device structure comprising:
a sub-fin structure disposed on a substrate, wherein the sub-fin structure comprises an epitaxial material, and wherein a first portion of the sub-fin structure is disposed within a portion of the substrate, and wherein a second portion of the sub-fin structure is disposed adjacent a dielectric material;
a fin device structure disposed on the sub-fin structure, wherein the fin device structure comprises the epitaxial material; and
a liner disposed between the second portion of the sub-fin structure and the dielectric material.

35. The structure of claim 34 further comprising wherein the epitaxial material comprises a material selected form the group consisting of gallium nitride, indium phosphide, indium aluminum phosphide and indium gallium nitride.

36. The structure of claim 34 further comprising wherein the liner material is selected from the group consisting of silicon nitride, silicon oxy nitride, hafnium oxide, and aluminum oxide, and does not comprise the same material as the dielectric material.

37. The structure of claim 34 further comprising wherein the liner comprises a thickness below about 100 angstroms.

38. The structure of claim 34 wherein a portion of the fin device structure comprises a channel region of a transistor structure, and wherein source/drain regions are coupled with the channel region.

39. The structure of claim 38 further comprising wherein a gate oxide is disposed on the channel region, and wherein a gate material is disposed on the gate oxide.

40. The structure of claim 34 further comprising wherein the silicon substrate comprises a p type silicon substrate.

41. The structure of claim 34 further comprising a system comprising:
a communications chip communicatively coupled to the microelectronic device; and
an eDRAM communicatively coupled to the communication chip.

42. The structure of claim 34 further comprising wherein the liner is not disposed on the fin device structure.

43. The structure of claim 34 further comprising wherein a portion of the liner is disposed between the substrate and the isolation material.

44. A method of forming a microelectronic device comprising:
forming an epitaxial material in an opening of an isolation material disposed on a substrate, the epitaxial material comprising:
a first portion disposed within a portion of the substrate;
a second portion disposed adjacent the isolation material, wherein a liner material is disposed between the isolation material and the second portion; and
a third portion disposed on the second portion, wherein the third portion comprises a fin device structure;
forming a gate oxide on a channel region of the fin device structure; and forming a gate material disposed on the gate oxide.

45. The method of claim 44 further comprising wherein the microelectronic device comprises a device selected from the group consisting of portion a multi-gate transistor and a gate all around transistor.

46. The method of claim 44 further comprising wherein the opening is formed by:
providing a sacrificial fin on the substrate;
forming the liner on the sacrificial fin and on the substrate;
forming the isolation material on the liner;
removing the sacrificial fin, wherein the liner is disposed on the sidewalls of the isolation material and on the substrate.

47. The method of claim 44 further comprising wherein the liner material comprises a material selected from the group consisting of silicon nitride, silicon oxy nitride, hafnium oxide, and aluminum oxide.

48. The structure of claim 44 further comprising wherein a portion of the liner is disposed between the substrate and the isolation material.

49. The method of claim 44 further comprising wherein the silicon substrate comprises a p type silicon substrate, and wherein sidewalls of a substrate interface with the epitaxial material comprise (111) silicon planes.

50. The method of claim 44 further comprising wherein the liner is disposed directly on the gate oxide.
